(19) United States
(12) Patent Application Publication
(10) Pub. No.: US 2006/0118917 A1
(43) Pub. Date: Jun. 8, 2006

(54) Shallow trench isolation and fabricating method thereof

(76) Inventors: Yoyi Gong, Hsinchu City (TW); Tony Lin, Hsinchu City (TW); Jung-Tsung Tseng, Sijhih City (TW); Abula Yu, Sinjhuang City (TW)

Correspondence Address: J.C. Patents;Suite 250, 4 Venture, Irvine, CA, 92618, US

(21) Appl. No.: 11/340,035

(22) Filed: Jan. 26, 2006

Related U.S. Application Data
(62) Division of application No. 10/697,771, filed on Oct. 29, 2003.

(51) Int. Cl. H01L 29/06

(52) U.S. Cl. 257/622

(57) ABSTRACT

A shallow trench isolation (STI) structure and fabricating method thereof is provided. A substrate is provided. A patterned mask layer is formed over the substrate. Using the patterned mask layer as an etching mask, the substrate is patterned to form a trench. A nitridation process is performed to form a silicon nitride liner on the surface of the trench. An insulating material is deposited to fill the trench. Since the silicon nitride liner within the STI is very thin, residual stress within the substrate is reduced, and the silicon nitride liner has very little or negligible impact on the trench aspect ratio.

### BACKGROUND OF THE INVENTION

1. Field of the Invention

The present invention relates to a semiconductor device structure and fabricating method thereof. More particularly, the present invention relates to a shallow trench isolation and fabricating method thereof.

2. Description of the Related Art

With the rapid development of integrate circuits, device miniaturization for higher integration is a major trend. As the dimension of each device is reduced and the level of integration is increased, the dimension of the isolation structures between devices must be reduced as well. In other words, more sophisticated techniques for isolating devices must be used as distance of separation between devices is reduced. At present, shallow trench isolation is often used in the fabrication of sub-half micron or smaller integrated circuits.

To produce a shallow trench isolation (STI) structure, a trench is formed in a semiconductor substrate. Thereafter, an oxide material is deposited into the trench serving as an isolation layer. Since the STI structure has the advantage of easy size adjustment but without the disadvantage of the bird's beak encroachment problem as in the case of a conventional local oxidation (LOCOS) isolation technique, and therefore ideal for fabricating sub-half micron or smaller metal-oxide-semiconductor (MOS).

The earlier version of the STI structure is fabricated simply by filling a substrate trench with an insulating material. However, due to the presence of residual stress around the peripheral substrate, dislocation of the lattice is common. This lattice dislocation is often the cause of current leakage. One common method of relieving residual stress is to form a silicon nitride liner between the trench surface and the layer of insulating material.

In general, the silicon nitride liner in a STI structure has a thickness greater than 120 Å. Hence, for a narrow trench having a width of 0.13 μm or smaller, the trench aspect ratio will increase considerably and the subsequent deposition of insulating material into the trench will be difficult. Furthermore, a few silicon nitride particles may be retained on the wafer after the formation of the liner. Since these silicon nitride particles have considerable adverse effects on the quality of the wafer, silicon nitride liner is no longer formed on a trench with a width of 0.13 μm or smaller. Yet, without the silicon nitride liner, residual stress problem persists.

An alternative method of reducing residual stress around the trench is to increase the temperature during the densification of the insulating material so that the peripheral lattice is realigned to relieve stress and reduce the number of dislocations. However, the densification temperature must not be too high (or processed too long) to prevent dopant diffusion. Ultimately, the degree of residual stress relaxation is quite limited.

### SUMMARY OF THE INVENTION

Accordingly, one object of the present invention is to provide a shallow trench isolation (STI) structure and fabricating method thereof capable of relieving residual stress around the trench region to eliminate possible effects on subsequent processing operations.

A second object of this invention is to provide a shallow trench isolation (STI) structure and fabricating method thereof capable of relieving residual stress around the trench region with very little or negligible impact on the trench aspect ratio.

To achieve these and other advantages and in accordance with the purpose of the invention, as embodied and broadly described herein, the invention provides a method of fabricating a shallow trench isolation structure. First, a substrate is provided. A patterned mask layer is formed over the substrate. Using the mask layer as an etching mask, the substrate is patterned to form a trench. Thereafter, a nitridation process is performed to form a silicon nitride liner on the surface of the trench. The nitridation process comprises a furnace treatment, a rapid thermal treatment or a plasma treatment. Finally, an insulating material is deposited to fill the trench.

Because the thickness of the silicon nitride liner formed by a nitridation process is very small (50 Å to 60 Å), the silicon nitride liner has very little or negligible impact on the trench aspect ratio. In other words, the silicon nitride liner is capable of relieving residual stress on the peripheral region of the substrate, and the insulating material can be easily filled into the trench in the subsequent process.

This invention also provides a shallow trench isolation (STI) structure. The STI structure comprises a substrate, a silicon nitride liner and an insulation layer. The substrate has a trench and the silicon nitride liner is formed on the surface of the trench. The silicon nitride liner has a thickness between 50 Å to 60 Å. Furthermore, the insulation layer completely fills the trench so that the insulation layer and the surface of the trench are separated from each other by the silicon nitride liner.

Since the thickness of the silicon nitride liner between the trench surface and the insulation layer of the STI structure is smaller than the conventional liner (>120 Å), its impact on the trench aspect ratio is small or negligible. Hence, the process of filling the trench with an insulating material can be carried out with ease.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a flow chart showing the steps for fabricating a shallow trench isolation structure according to one preferred embodiment of this invention.

FIGS. 2A through 2E are schematic cross-sectional views showing the progression of process steps for fabricating the STI structure in FIG. 1.

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

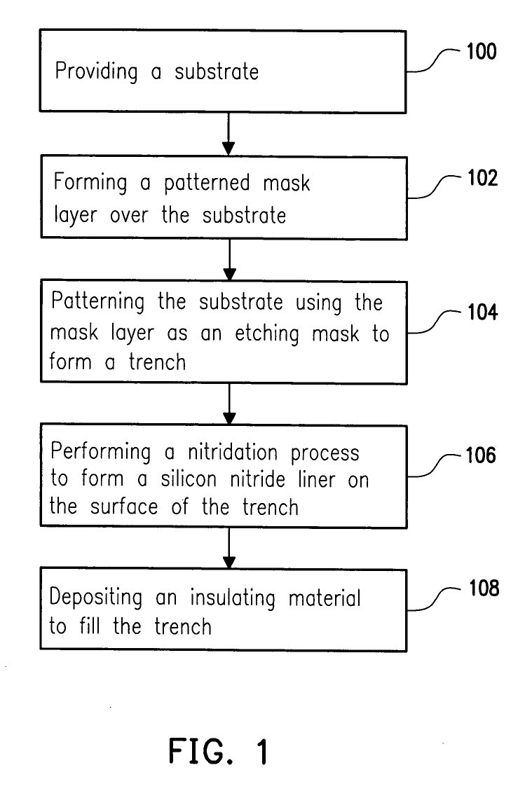

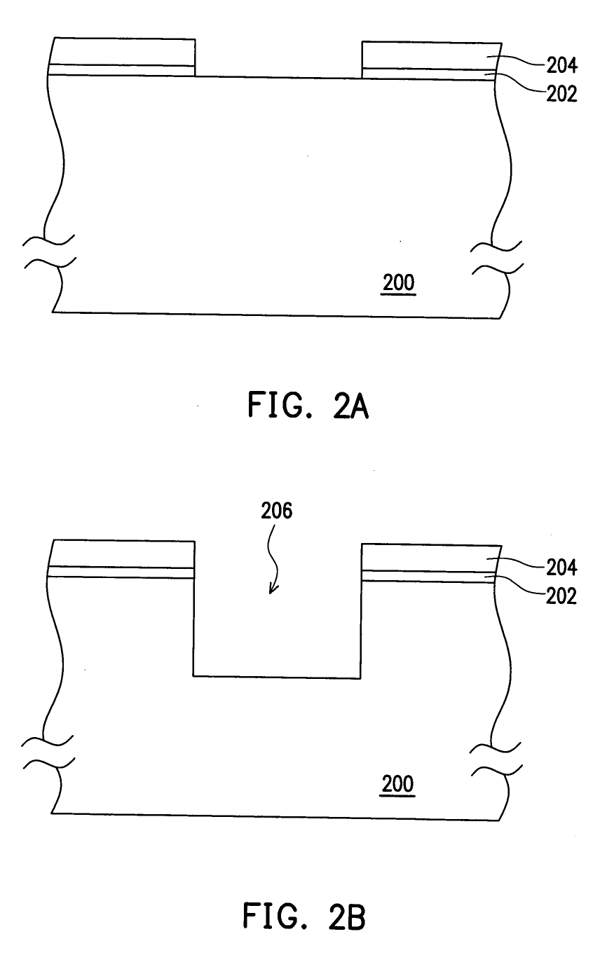

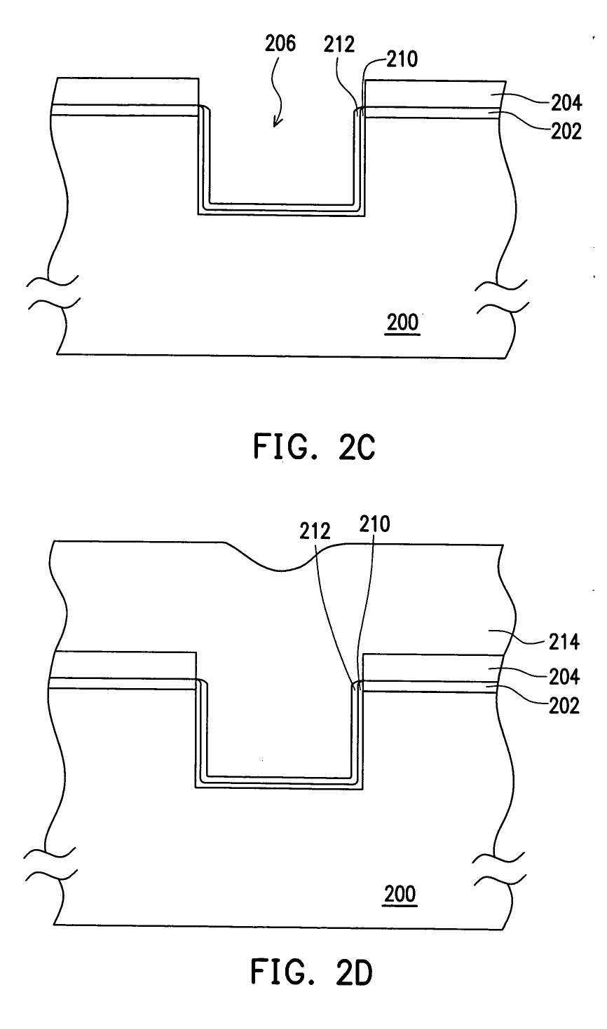

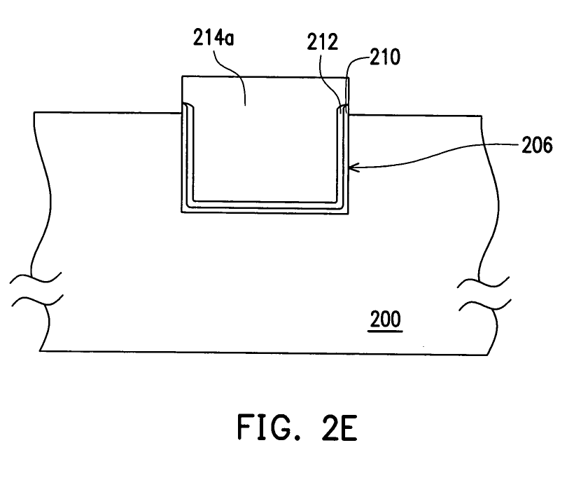

FIG. 1 is a flow chart showing the steps for fabricating a STI structure according to one preferred embodiment of this invention. FIGS. 2A through 2E are schematic cross-sectional views showing the progression of process steps for fabricating the STI structure in FIG. 1. As shown in FIGS. 1 and 2A, a substrate is provided (step 100). A patterned mask layer 204 is formed over the substrate 200 (step 102). The patterned mask layer 204 has an opening that exposes a portion of the substrate 200. The mask layer 204 is a silicon nitride layer formed, for example, by depositing mask material over the substrate 200 globally to form a mask layer (not shown). Thereafter, a patterned photoresist layer is formed over the mask layer and the mask layer is patterned using the patterned photoresist layer. After patterning the mask layer, the patterned photoresist layer is removed.

In addition, a pad oxide layer 202 may also be formed over the substrate 200 before forming the global mask layer to lower the stress between the substrate 200 and the mask layer 204. The pad oxide layer 202 is also patterned in the subsequent patterning process of the mask layer 204. The pad oxide layer 202 is formed, for example, by performing a thermal oxidation process.

As shown in FIGS. 1 and 2B, the substrate 200 is etched using the mask layer 204 as an etching mask to form a trench 206 (step 104). The etching process includes an anisotropic dry etching operation, for example.

As shown in FIGS. 1 and 2C, a nitridation process 106 is performed to form a silicon nitride liner 212 with a thickness between 50 Å to 60 Å on the surface of the trench 206. The nitridation process 106 can be comprised of a furnace treatment, a rapid thermal treatment or a plasma treatment, for example. The furnace treatment or the rapid thermal treatment is carried out in an atmosphere of gaseous nitrogen and the plasma treatment is carried out using nitrogen plasma.

It is to be noted that the silicon nitride liner 212 produced by the nitridation process 106 is very thin. Accordingly, the silicon nitride liner layer 212 will have negligible impact on the trench 206 aspect ratio. In other words, an insulating material can be deposited to fill the trench (in step 108) without much difficulties. Furthermore, because the silicon nitride liner 212 is directly formed on the surface of the trench 206 in a nitridation process 106, the problem of wafer contamination by silicon nitride particles will not occur. In addition, the nitridation process 106 may also be integrated with the fabrication of the liner oxide layer. For doing so, all one need to do is adding some gaseous nitrogen to the thermal oxidation process for forming the liner oxide layer 210 on the surface of the trench 206. In fact, the silicon nitride liner 212 is formed in-situ over the liner oxide layer 210.

As shown in FIGS. 1 and 2D, an insulation layer 214 is formed over the substrate 200 completely filling the trench (step 108). The insulation layer 214 is a silicon oxide layer and can be formed, for example, by performing a high-density plasma chemical vapor deposition (HDPCVD) process. Since the silicon nitride liner 212 formed in step 106 is relatively thin, its impact on the trench 206 aspect ratio is minimal. In other words, the silicon nitride liner 212 has very little negligible impact on the filling of the trench 202 with an insulating material 214 in step 108.

As shown in FIG. 2E, the insulation layer 214 outside the trench 206 is removed by performing chemical-mechanical polishing (CMP) operation. Consequently, only the insulation layer 214a is retained inside the trench 206. Finally, the pad oxide layer 202 on the substrate 200 and the mask layer 204 are removed. Thus, the process of fabricating a shallow trench isolation (STI) structure is completed.

In summary, the nitridation process according to this invention is capable of producing a thin silicon nitride liner. The silicon nitride liner of the present invention has very little or negligible impact on the trench aspect ratio, and therefore the insulating material can be easily filled into the trench for fabricating highly integrated circuits. Furthermore, because the nitridation treatment is directly carried out on the trench surface, therefore the problem of silicon nitride particles contaminating the wafer as in case of the conventional process as described above can be effectively resolved.

As shown in FIG. 2E, a shallow trench isolation (STI) structure according to this invention comprises a substrate 200, a silicon nitride liner 212 and an insulation layer 214a. The substrate 200 comprises a trench 206. The silicon nitride liner 212 is formed on the surface of the trench 206. The silicon nitride liner 212 has a thickness in a range of about 50 Å to 60 Å. The insulation layer 214a fills the trench 206 completely. The insulation layer 214a is comprised of a silicon oxide layer, for example. The STI structure furthermore comprises a liner oxide layer 210 set between the surface of the trench 206 and the silicon nitride liner 212.

Accordingly, the silicon nitride liner between the surface of the trench and the insulation layer has a thickness smaller than the silicon nitride layer in a conventional STI structure. Therefore, the silicon nitride liner of the present invention will have a very little or negligible impact on the trench aspect ratio so that the trench can be reliably filled during the trench-filling process. In the meantime, the silicon nitride liner of the present invention within the STI structure is capable of relieving the residual stress around the peripheral region of the substrate, and thus the reliability of the semiconductor device can be effectively promoted.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

1. A method of fabricating a shallow trench isolation (STI) structure, comprising the steps of:
providing a substrate;
forming a patterned mask layer over the substrate;
patterning the substrate using the mask layer as an etching mask to form a trench in the substrate;
performing a nitridation process to form a silicon nitride liner on the surface of the trench, wherein the nitridation process comprises performing a plasma process; and
depositing an insulating material over the trench and filling the trench with the insulating material.

2-6. (canceled)

7. The method of claim 1, wherein the plasma process comprises performing a nitrogen plasma treatment.

8. The method of claim 1, further comprising forming a liner oxide layer over the substrate, wherein the formation of the liner oxide layer and the nitridation process for forming the silicon nitride liner are performed in-situ.

9. The method of claim 8, wherein the step of forming the liner oxide layer comprises performing a thermal oxidation and integrating the thermal oxidation process with the nitridation process by introducing gaseous nitrogen mid-way through the thermal treatment.

10-11. (canceled)
